(19) United States
(12) Patent Application Publication
(10) Pub. No.: US 2026/0073637 A1
(43) Pub. Date: Mar. 12, 2026

(54) Method of Parametric Design for Custom-Fit Eyewear Frames

(71) Applicant: Georgia Tech Research Corporation, Atlanta, GA (US)

(72) Inventors: Yuanqing Tian, Atlanta, GA (US); Roger M. Ball, Atlanta, GA (US)

(21) Appl. No.: 18/828,669

(22) Filed: Sep. 9, 2024

(51) Int. Cl. G06T 19/00; G06F 30/12; G06T 7/60; G06T 17/00

(52) U.S. Cl. CPC G06T 19/00; G06F 30/12; G06T 7/60; G06T 17/00; G06T 2207/30108; G06T 2207/30196

(57) ABSTRACT

The present invention includes a method for creating custom eyewear. The method may include obtaining a model of at least a portion of a head of a user, determining a set of body parameters, determining values for a set of adjustable parameters, and generating a custom eyewear design data file. The model may comprise a plurality of user features. The set of body parameters may be based at least in part on the plurality of user features. The set of body parameters may comprise a plurality of landmarks. Generating the custom eyewear design data file may include determining generating a stretchable parametric model. The stretchable parametric model may be based at least in part on the set of body parameters. The custom eyewear design data file may be generated based at least in part on the stretchable parametric model and the values for the set of adjustable parameters.

### FIELD OF THE DISCLOSURE

The various embodiments of the present disclosure relate generally to custom eyewear design, and more specifically to methods for creating custom eyewear designs.

### BACKGROUND

Over half of the adult population of the world use prescription eyewear to protect or correct their vision. People wear glasses to safely navigate their environment and for specialized tasks like driving or reading. Invented in the 13^{th} century, eyewear products have evolved into essential daily-use consumer goods. Well-fitted eyewear improves the quality of the wearers' lives by bringing the world into sharper focus and correcting the degraded vision caused by aging, but poorly fitting eyewear causes discomfort, dizziness, and blurred vision.

Today's eyewear industry is a massive business that produces a variety of styles, shapes and sizes for its customers across the globe. Designing prescription eyewear starts with a multi-step optical examination to prescribe the right corrective lenses for a person's vision. This is followed by a try-on session to find the eyeglass frame that best fits the subject's face. The optician then assembles the corrective prescription lenses into the frame and uses a frame warmer to make fit adjustments like bending the frame arms to lengthen them or altering the angle of the frame to better fit the customer's face. The vision is checked one last time with the adjusted frame and the process is complete.

Most of the current eyeglass frames are designed using proportional grading or scaling approach based on interpupillary distance in correlation with face width and temple length. This traditional design method fails to address the full diversity of human face morphology. Human face morphology varies widely according to ancestry, age, and gender. In Marcha and Angus's study on evaluating and designing eyewear fit for South African populations, their results showed that both “Asian fit” and “Regular fit” eyewear frames were not suited to the facial structures of the South African population. In addition to variations in populations, the diversity among individuals can also result in a poor fit. Critically, the rigid proportion or correlation approach does not always account for individual face shapes. For example, a person with a wide face but a narrow nose bridge will not achieve a proper fit with these pre-defined sizes. Outliers with extreme head-and-face morphologies fall outside of the current eyeglasses market.

With the rising awareness of these fit-related problems, design researchers have been exploring new solutions to offer better-fitting eyewear. One solution for improved fit is to offer customized eyeglasses frames on an individual basis. A new parametric design method is proposed for creating custom eyeglass frames.

### BRIEF SUMMARY

An exemplary embodiment of the present disclosure provides a method for creating custom eyewear. The method may include obtaining a model of at least a portion of a head of a user, determining a set of body parameters, determining values for a set of adjustable parameters, and generating a custom eyewear frame design data file. The model of the head of the user may include a plurality of user features. Determining a set of body parameters may be based at least in part on the plurality of user features. The set of body parameters may include a plurality of landmarks. Generating the custom eyewear frame design data file may be based at least in part on the set of body parameters and the set of adjustable parameters.

In any of the embodiments disclosed herein, the method may further include fabricating a custom eyewear frame. The custom eyewear frame may be fabricated based at least in part on the custom eyewear frame design data file.

In any of the embodiments disclosed herein, the method may further include selecting a generic frame design from a plurality of generic eyewear frame designs. The set of adjustable parameters may be associated with the generic eyewear frame design.

In any of the embodiments disclosed herein, the set of body parameters may include a plurality of facial dimensions. The plurality of facial dimensions may be based at least in part on the plurality of landmarks.

In any of the embodiments disclosed herein, the plurality of facial dimensions may include forehead contour, nasial tilt, pupil position, eye orbit length, eye orbit height, eye length, hinge, head breadth, back of ear contour, nose bridge contour, or any combination thereof.

In any of the embodiments disclosed herein, the set of adjustable parameters may include one or more aesthetic parameters and one or more comfort factors. The values for the set of adjustable parameters may be based at least in part on one or more user preferences.

In any of the embodiments disclosed herein, the one or more aesthetic parameters may include frame style, lens size, arm style, arm length, frame width, or any combination thereof.

In any of the embodiments disclosed herein, the one or more comfort factors may include a vertex distance, an arm breadth, a nose pad, a frame grip, or any combination thereof.

In any of the embodiments disclosed herein, generating the custom eyewear frame design data file may include determining a set of fit factors, generating a stretchable parametric model, and generating the custom eyewear frame design data file. Generating the stretchable parametric model may be based at least in part on the set of body parameters and the set of fit factors. Generating the custom eyewear frame design data file may be based at least on part on the values for the set of adjustable parameters.

In any of the embodiments disclosed herein, the set of fit factors may include a quantitative fit factor, a contact fit factor, an interference fit factor, a ventilated fit factor, or any combination thereof.

In any of the embodiments disclosed herein, generating the custom eyewear frame design data file may further include manually adjusting the values for the set of adjustable parameters to alter the stretchable parametric model.

In any of the embodiments disclosed herein, fabricating the custom eyewear frame may include generating a CAD model of the custom eyewear frame, and manufacturing the CAD model via additive manufacturing. Generating the CAD model of the custom eyewear frame may be based at least in part on the custom eyewear frame design data file.

An exemplary embodiment of the present disclosure provides a method for creating custom eyewear. The method may include receiving a scan of at least a portion of a head of a user, identifying a plurality of landmarks, determining a set of body parameters, generating a stretchable parametric model, determining values for a set of adjustable parameters, and generating a custom eyewear frame design data file. Identifying the plurality of landmarks may be based at least in part on the scan. Determining the set of body parameters may be based at least in part on the plurality of landmarks. Generating the stretchable parametric model may be based at least in part on the set of body parameters. The values for the set of adjustable parameters may be associated with the stretchable parametric model. Generating the custom eyewear frame design data file may be based at least in part on the stretchable parametric model and the values for the set of adjustable parameters.

In any of the embodiments disclosed herein, the method may further include fabricating a custom eyewear frame. The custom eyewear frame may be based at least in part on the custom eyewear frame design data file.

In any of the embodiments disclosed herein, identifying the plurality of landmarks may include inputting the scan into a landmark identification software, and outputting, via the landmark identification software, a coordinate location of each of the plurality of landmarks.

In any of the embodiments disclosed herein, the stretchable parametric model may be a wire frame model.

In any of the embodiments disclosed herein, the stretchable parametric model may be automatically generated based at least in part on the set of body parameters.

In any of the embodiments disclosed herein, the stretchable parametric model may include one or more frames, one or more lens cavities, one or more hinges, one or more arms, a nose bridge, or any combination thereof.

In any of the embodiments disclosed herein, the stretchable parametric model may be based at least in part on a body product relationship.

In any of the embodiments disclosed herein, the body product relationship may be based at least in part on a front frame position, a face wrap, a pantoscopic tilt, a vertex distance, a front frame size, a hinge component, a lens cavity size, an eyeglasses arm, a nose bridge, or any combination thereof.

These and other aspects of the present disclosure are described in the Detailed Description below and the accompanying drawings. Other aspects and features of embodiments will become apparent to those of ordinary skill in the art upon reviewing the following description of specific, exemplary embodiments in concert with the drawings. While features of the present disclosure may be discussed relative to certain embodiments and figures, all embodiments of the present disclosure can include one or more of the features discussed herein. Further, while one or more embodiments may be discussed as having certain advantageous features, one or more of such features may also be used with the various embodiments discussed herein. In similar fashion, while exemplary embodiments may be discussed below as device, system, or method embodiments, it is to be understood that such exemplary embodiments can be implemented in various devices, systems, and methods of the present disclosure.

### BRIEF DESCRIPTION OF THE DRAWINGS

The following detailed description of specific embodiments of the disclosure will be better understood when read in conjunction with the appended drawings. For the purpose of illustrating the disclosure, specific embodiments are shown in the drawings. It should be understood, however, that the disclosure is not limited to the precise arrangements and instrumentalities of the embodiments shown in the drawings.

FIG. 1 provides a block diagram of an exemplary method for custom-fit eyewear design.

FIG. 2 provides a block diagram of another exemplary method for custom-fit eyewear design.

FIGS. 3A-3B provide a model of at least a portion of a head of a user having a plurality of landmarks.

FIG. 4 provides a model of at least a portion of a head of a user having a plurality of facial dimensions.

FIG. 5 provides a custom eyewear frame design having a plurality of frame dimensions and a plurality of frame components.

FIGS. 6A-6D provide an exemplary embodiment of positioning a stretchable parametric model.

FIGS. 7A-7F provide an exemplary embodiment of constructing a stretchable parametric model.

FIG. 8 provides an exemplary embodiment of an algorithm for generating the stretchable parametric model.

FIG. 9 provides an exemplary embodiment of an interface for adjusting the values for the plurality of adjustable parameters.

FIG. 10 provides an exemplary embodiment of an interface for adjusting the values for the plurality of adjustable parameters associated with the nose bridge.

FIG. 11 provides an exemplary embodiment of a first user having a first model and a first custom eyewear frame and a second user having a second model and a second custom eyewear frame.

### DETAILED DESCRIPTION

To facilitate an understanding of the principles and features of the present disclosure, various illustrative embodiments are explained below. The components, steps, and materials described hereinafter as making up various elements of the embodiments disclosed herein are intended to be illustrative and not restrictive. Many suitable components, steps, and materials that would perform the same or similar functions as the components, steps, and materials described herein are intended to be embraced within the scope of the disclosure. Such other components, steps, and materials not described herein can include, but are not limited to, similar components or steps that are developed after development of the embodiments disclosed herein.

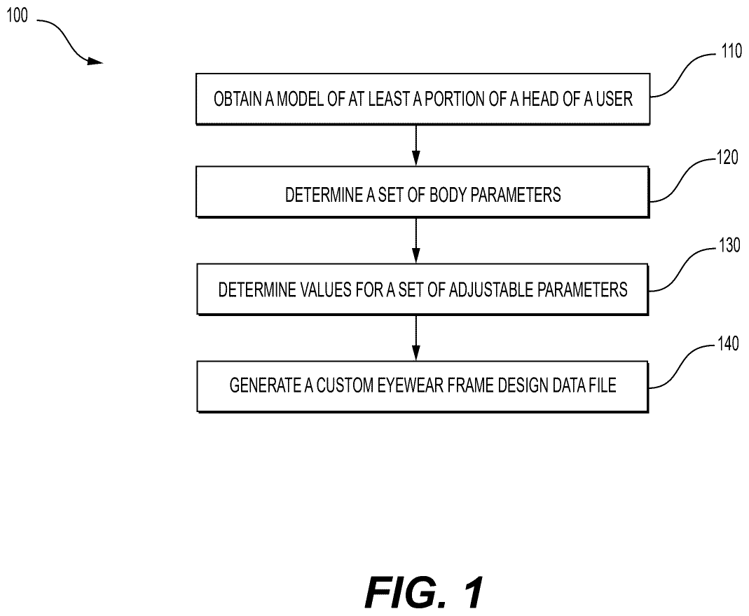

As shown in FIG. 1, an exemplary embodiment of the present disclosure provides a method for creating custom eyewear 100. In some embodiments, the method 100 can include step 110, step 120, step 130, and step 140. Step 110, in some embodiments, can include obtaining a model of at least a portion of a head of a user. In some embodiments, the model can comprise a plurality of user features. The model, in an example embodiment, can be a 3D model in a design software. In another example embodiment, the model can be a physical model, which may be fabricated based at least in part on the 3D model in the design software. Step 120, in some embodiments, can include determining a set of body parameters. In some embodiments, the set of body parameters can be based at least in part on the plurality of user features. The set of body parameters, in some embodiments, can comprise a plurality of landmarks. In an example embodiment, the set of body parameters can further comprise a plurality of facial dimensions, wherein the plurality of facial dimensions can be based at least in part on the plurality of landmarks. In exemplary embodiments, the plurality of facial dimensions can comprise forehead contour, nasial tilt, pupil position, eye orbit length, eye orbit height, eye length, hinge, head breadth, back of ear contour, nose bridge contour, or any combination thereof. Step 130, in some embodiments, can include determining values for a set of adjustable parameters. The set of adjustable parameters, in some embodiments, can comprise one or more aesthetic parameters and one or more comfort factors. In an exemplary embodiment, the values for the set of adjustable parameters are based at least in part on one or more user preferences. The one or more aesthetic parameters, in an exemplary embodiment, can comprise frame style, lens size, arm style, or any combination thereof. The one or more comfort factors, in an exemplary embodiment, can comprise a vertex distance, an arm breadth, a nose pad, or any combination thereof. Step 140, in some embodiments, can include generating a custom eyewear frame design data file. In some embodiments, generating the custom eyewear frame design data file can comprise: determining a set of fit factors; generating a stretchable parametric model, and generating the custom eyewear design data file. Generating the stretchable parametric model, in some embodiments, can be based at least in part on the set of body parameters and the set of fit factors. Generating the custom eyewear frame design data file, in some embodiments, can be based at least in part on the stretchable parametric model and the values for the set of adjustable parameters. In an exemplary embodiment, the set of fit factors can comprise a quantitative fit factor, a contact fit factor, an interference fit factor, a ventilated fit factor, or any combination thereof. Generating the custom eyewear frame design data file, in an example embodiment, can comprise manually adjusting the values for the set of adjustable parameters to alter the stretchable parametric model.

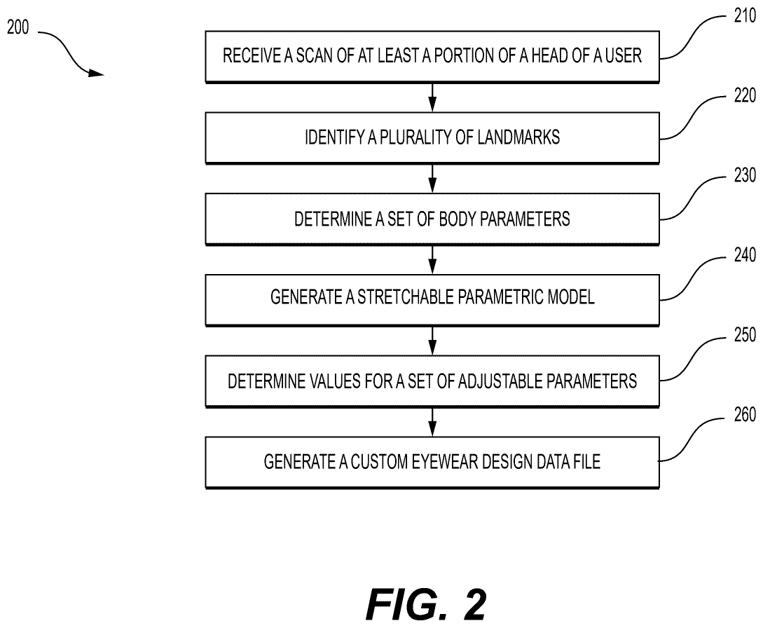

As shown in FIG. 2, an exemplary embodiment of the present disclosure provides a method for creating custom eyewear 200. The method 200 can include step 210, step 220, step 230, step 240, step 250, and step 260. Step 210, in some embodiments, can comprise receiving a scan of at least a portion of a head of a user. Step 220, in some embodiments, can comprise identifying a plurality of landmarks. In some embodiments, identifying the plurality of landmarks can be based at least in part on the scan. In an exemplary embodiment, identifying the plurality of landmarks can comprise: inputting the scan into a landmark identification software; and outputting, via the landmark identification software, a coordinate location of each of the plurality of landmarks. Step 230, in some embodiments, can comprise determining a set of body parameters. In some embodiments, the determining the set of body parameters can be based at least in part on the plurality of landmarks. Step 240, in some embodiments, can comprise generating a stretchable parametric model. In some embodiments, generating the stretchable parametric model can be based at least in part on the set of body parameters. In an exemplary embodiment, the stretchable parametric model can be a wire frame model. In another exemplary embodiment, the stretchable parametric model can be automatically generated based at least in part on the set of body parameters. The stretchable parametric model can comprise one or more front frames, one or more lens cavities, one or more hinges, one or more arms, a nose bridge, or any combination thereof. The stretchable parametric model, in some embodiments, can be based at least in part on a body product relationship. The body product relationship can be based at least in part on a front frame position, a face wrap, a pantoscopic tilt, a vertex distance, a front frame size, a hinge component, a lens cavity size, an eyeglasses arm, a nose bridge, or any combination thereof.

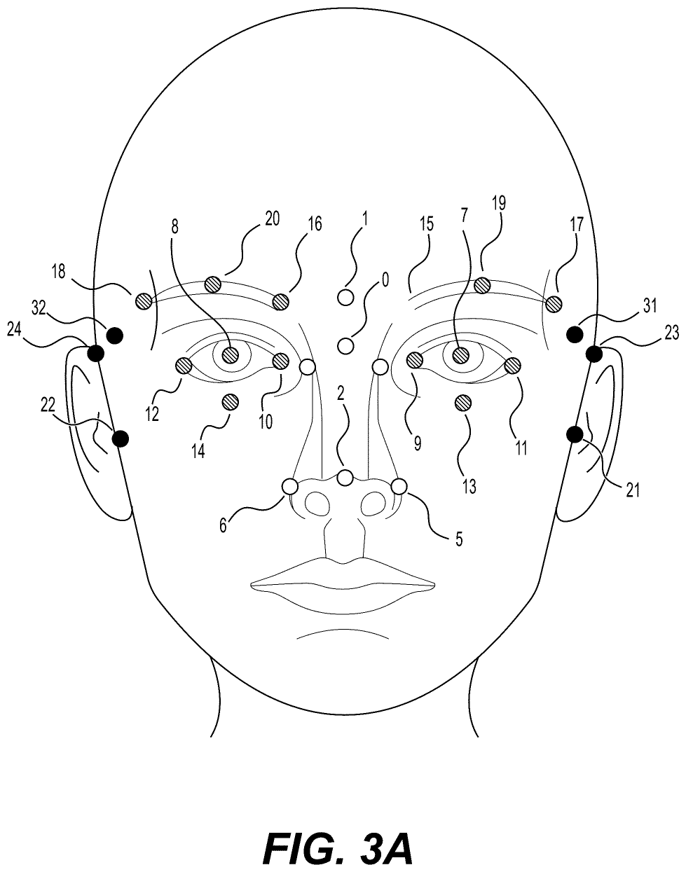

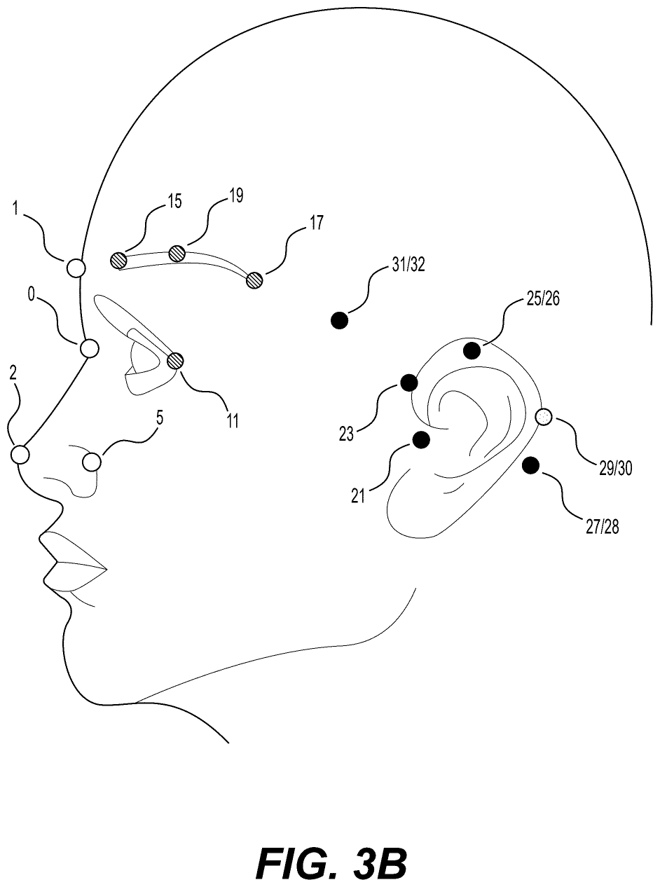

An exemplary embodiment of the plurality of landmarks is illustrated in FIGS. 3A and 3B. In some embodiments, the plurality of landmarks can be grouped into groups of landmarks, wherein the groups of landmarks can comprise a nose group, an eye group, an ear group, and any combination thereof. The nose group, in an exemplary embodiment, can comprise one or more of a sellion 0, a glabella 1, a pro-nasal 2, a nasal root left 3, a nasal root right 4, an alare left 5, and an alare right 6. The eye group, in an exemplary embodiment, can comprise a pupil left 7, a pupil right 8, an ectocanthion left 9, an ectocanthion right 10, an ectocanthus left 11, an ectocanthus right 12, an infraorbital left 13, an infraorbital right 14, an eyebrow medial left 15, an eyebrow medial right 16, an eyebrow lateral left 17, an eyebrow lateral right 18, an eyebrow middle left 19, an eyebrow middle right 20, and any combination thereof. The ear group, in an exemplary embodiment, can comprise a tragion left 21, a tragion right 22, an otobasion superius left 23, an otobasion superius right 24, an upper ear base point (UEBP) left 25, a UEBP right 26, a lateral mastoid point (LMP) left 27, a LMP right 28, a posterior ear base point (PEBP) left 29, a PEBP right 30, a temple left 31, a temple right 32, and any combination thereof. In some embodiments, the plurality of landmarks can be identified via physical markings prior to subjecting the user to the scan. In an exemplary embodiment, the plurality of landmarks can include a group of virtual landmarks, wherein the group of virtual landmarks may not be able to be physically marked due to safety considerations. In some embodiments, the group of virtual landmarks can include the pupil left 7, the pupil right 8, the ectocanthion left 9, the ectocanthion right 10, the ectocanthus left 11, and the ectocanthus right 12, or any combination thereof.

In an example embodiment, the plurality of landmarks can be identified via a machine learning (ML) system. The ML system, in some embodiments, can be a convolutional neural network. In the example embodiment, the ML system can receive training data, receive the scan of the user, identify each of the plurality of landmarks based at least in part on the training data, and output locations of each of the plurality of landmarks. Outputting the locations of each of the plurality of landmarks, in some embodiments, can comprise outputting a file readable into a 3D modeling software, wherein the locations of each of the plurality of landmarks can be evident to a designer using the 3D modeling software.

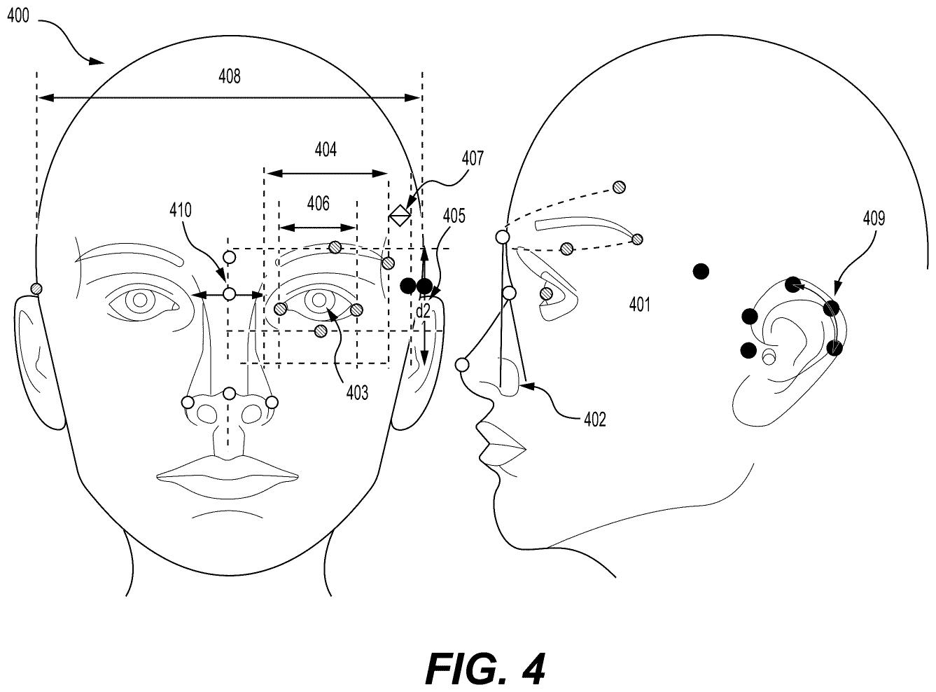

Referring to FIG. 4, an exemplary embodiment of the plurality of facial dimensions 400 is illustrated. In some embodiments, the plurality of facial dimensions 400 can include but is not limited to a forehead contour 401, a nasial tilt 402, a pupil position 403, an eye orbit length 404, an eye orbit height 405, an eye length 406, a hinge dimension 407, a head breadth 408, a back of ear contour 409, a nose bridge contour 410, or any combination thereof. In one embodiment, the plurality of facial dimensions 400 may be based at least in part on the plurality of landmarks. Values for the plurality of facial dimensions, in some embodiments, can be based at least in part on the location of the plurality of landmarks. In an exemplary embodiment, values for the plurality of facial dimensions can be automatically generated via the 3D modeling software based at least in part on the locations of the plurality of landmarks.

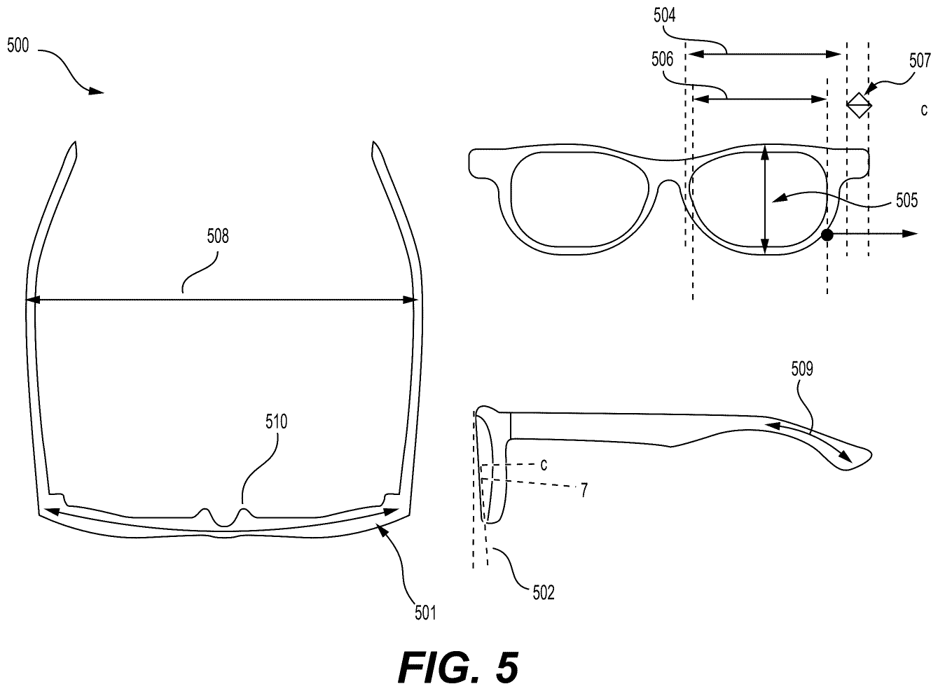

Referring to FIG. 5, an exemplary embodiment of the custom eyewear frame 500 having a plurality of frame dimensions and a plurality of frame components is illustrated. The stretchable parametric model, in some embodiments, may be based at least in part on the plurality of frame dimensions and the plurality of frame components. In some embodiments, the plurality of frame dimensions can include but is not limited to a face wrap 501, a pantoscopic tilt 502, a vertex distance 503, a front frame length 504, a front frame height 505, a lens cavity 506, a hinge 507, an arm breadth 508, an arm ear hang contour 509, a nose bridge 510, or any combination thereof. In an exemplary embodiment, the custom eyewear frame can include a plurality of frame components. The plurality of frame components, in some embodiments, can include a front from positioning, a front frame size, the lens cavity 506, the hinge 507, one or more arms, the nose bridge 510, or any combination thereof. The front frame positioning, in some embodiments, can be based at least in part on the face wrap 501, the pantoscopic tilt 502, the vertex distance 503, or any combination thereof. The front frame size, in some embodiments, may be based at least in part on the front frame length 504, the front frame height 505, or any combination thereof. The one or more arms, in some embodiments, may be based at least in part on the arm breadth 508, the arm ear hang contour 509, or any combination thereof.

According to some embodiments, the body product relationship may be based at least in part on the plurality of frame dimensions and the plurality of facial dimensions. In an exemplary embodiment, the body product relationship may be a set of mathematical relationships configured to tailor the stretchable parametric model to the plurality of landmarks. In some embodiments, the body product relationship may be based at least in part on the set of fit factors. The set of fit factors, in some embodiments, can include a quantitative fit factor, a contact fit factor, an interference fit factor, a ventilated fit factor, and any combination thereof. The quantitative fit factor may regulate the plurality of frame dimensions such that the stretchable parametric model may be constrained within a measured range or certain geometric equations based at least in part on the plurality of landmarks. The contact fit factor may relate to an interface of a hard surface of the stretchable parametric model with a soft surface of the user's skin. For example, the contact fit factor may be adjusted such that a surface of the front frame may rest lightly on a surface of the user's skin. The interference fit factor may determine a grip of a side of the head of the user by the custom eyewear frame. In an exemplary embodiment, the interference fit factor may prevent the custom eyewear frame from falling off the user's head when looking down or quickly moving the head. The ventilated fit factor may determine the space between the user's face and the custom eyewear frame. In some embodiments, the ventilated fit factor may allow for the free movement of air between the user's face and the custom eyewear frame. In an exemplary embodiment, the ventilated fit factor may ensure that the eyelashes of the user do not come into contact with the custom eyewear frame. The ventilated fit factor, in some embodiments, can be based at least in part on the need to dissipate localized heat buildup that may lead to lens fogging. In some embodiments, the body product relationship may be based at least in part on the front frame position, the face wrap, the pantoscopic tilt, the vertex distance, the front frame size, the hinge component, the lens cavity size, the eyeglasses arm, the nose bridge, or any combination thereof.

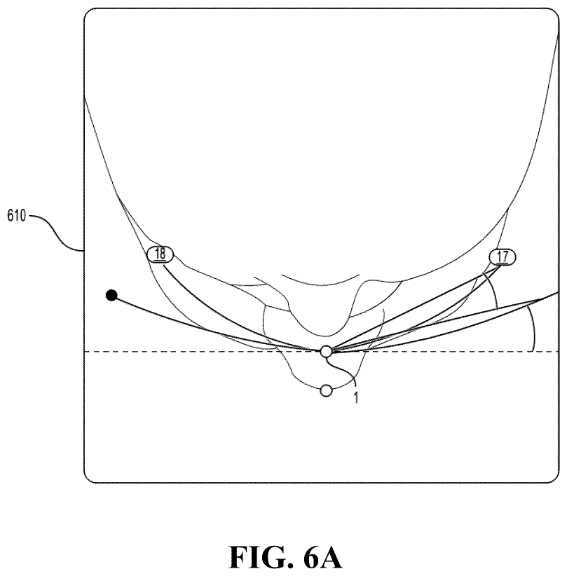

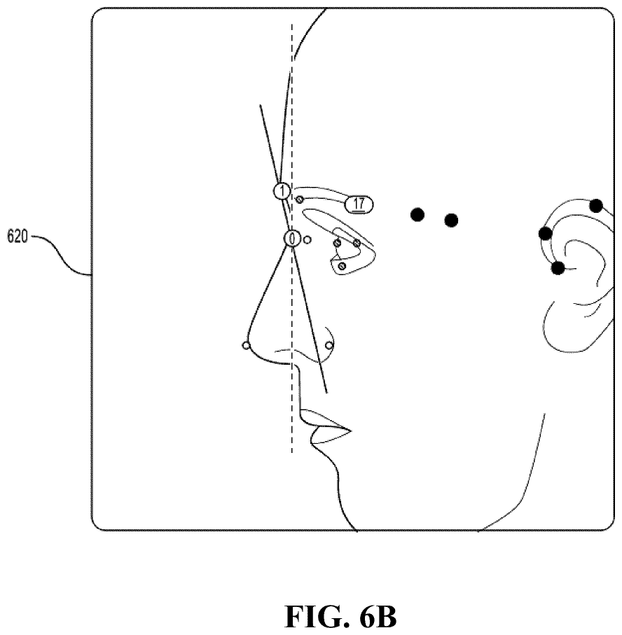

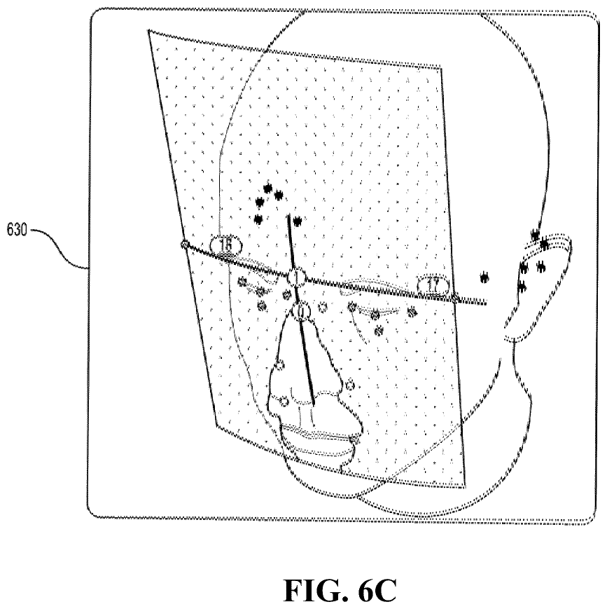

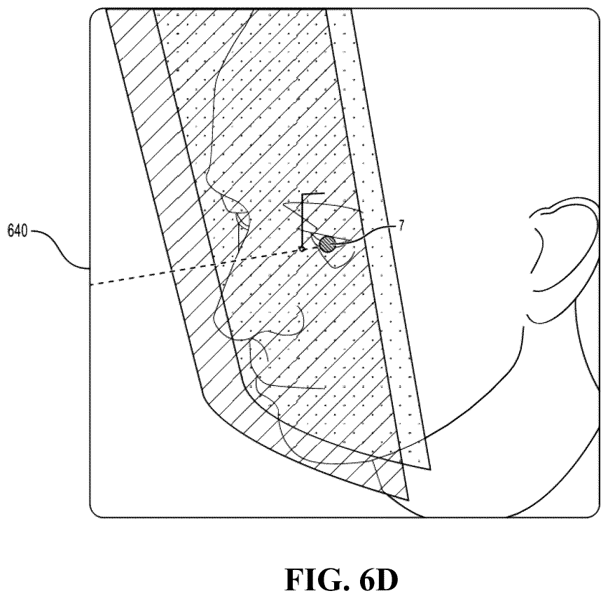

Referring to FIGS. 6A-6D, an exemplary embodiment of positioning the stretchable parametric model is shown. Positioning the stretchable parametric model can include a forehead contour step 610, a pantoscopic tilt step 620, a face wrap step 630, an adjustment step 640, or any combination thereof. The forehead contour step 610 may include determining the forehead contour 401. In some embodiments, determining the forehead contour 401 may be based at least in part on the plurality of landmarks, more specifically the glabella 1, the eyebrow lateral left 17, and the eyebrow lateral right 18. In one embodiment, determining the forehead contour 401 may include determining a face wrap contour. The pantoscopic tilt step 620 may include constructing the pantoscopic tilt 502. In some embodiments, constructing the pantoscopic tilt 502 may be based at least in part on the nasial tilt, the glabella 1, and the sellion 0. The face wrap step 530 may include determining the face wrap 501. In some embodiments, determining the face wrap 501 may be based at least in part on a face wrap contour and the pantoscopic tilt 502. The adjusting step 640 may include adjusting the face wrap 501. In some embodiments, adjusting the face wrap 501 may include adjusting a distance between the face wrap 501 and the pupil.

According to some embodiments, positioning the stretchable parametric model may also include positioning the one or more front frames, or adjusting a front frame position. The front frame positioning, in some embodiments, may refer to an overall front surface comprising one or more frame edges, one or more lenses, the nose bridge, and two hinges. In an exemplary embodiment, the front frame may conform to a face curvature profile of the user and may keep a proper distance from the pupils.

According to some embodiments, the face wrap 501 may describe a horizontal angle of the frame and lens surface in front of the face. In an exemplary embodiment, the face wrap 501 may be dependent on a style of the stretchable parametric model. In one embodiment, the face wrap may be customized to conform to the user's facial curvature. In an exemplary embodiment, a curved front surface of the eyewear frame may be constructed based at least in part on the glabella 1, the eyebrow lateral left 17, the eyebrow lateral right 18, or any combination thereof. In an exemplary embodiment, the front surface curvature is based at least in part on a halved angle, wherein the halved angle is based at least in part on an angle between the horizontal line and the forehead contour. The front frame and the lenses, in the exemplary embodiment, may be constructed on the front surface curvature.

According to some embodiments, the front surface position is based at least in part on the face wrap and the pantoscopic tilt. The pantoscopic tilt, in one embodiment, may describe a gradient on the front frame along a vertical direction. For example, in an example embodiment, a front frame will yield a slight inclination to conform to a tilted facial profile from an upper eyebrow area to a lower face area. In some embodiments, the pantoscopic tilt may be calculated based at least in part on the glabella 1, the sellion 0, and the nasial tilt 402. For example, a pantoscopic tilt angle value may be calculated by measuring angle between a reference line and a vertical axis. A curved and tilted front surface, in one embodiment, can be constructed based at least in part on the face wrap 501 and the pantoscopic tilt 502.

According to some embodiments, the vertex distance 503 may refer to a distance between the front frame and the pupil. An adjustable value range may be set to shift the front surface away from the pupil within a certain distance. In an exemplary embodiment, a recommended vertex distance 503 may range from 8 to 20 millimeters.

According to some embodiments, the front frame may contain two frame cavities. The frame cavities may be symmetrical on both eyes. The crucial dimensions for the front frame may be the front frame length 504 and the front frame height 505. In an exemplary embodiment, the front frame length 504 and the front frame height 505 may be correlated to the plurality of landmarks, specifically a group of the plurality of landmarks near the eye orbit. An example embodiment of the front frame length 504 may define the front frame length 504 as beginning at the nasal root point 3 and cover up to the eyebrow lateral points 17/18. The front frame height 505 may be an adjustable dimension. The front frame height 505 may be based at least in part on a frame style. The frame style may be associated with a generic eyewear frame design of a plurality of generic eyewear frame designs. In one embodiment, the front frame height may cover up to ⅔ of a nose height or maximal height. The eye orbit may demonstrate a referential dimension for the front frame height 505.

According to some embodiments, the hinge component may provide a connection between an end of the one or more frame edges and a start of a frame arm. In an exemplary embodiment, the hinge component may allow for the custom eyewear frame to be folded. The hinge component can extend, in some embodiments, from an outer edge of the frame (the eyebrow lateral point 17/18), but may not exceed the temple point 31/32. The hinge dimension 407 may represent the location of the hinge component. In some embodiments, the hinge component may be associated with the plurality of adjustable parameters. The plurality of adjustable parameters associated with the hinge may alter a height, a shape, and a radius. The plurality of adjustable parameters associated with the hinge component may be associated with the frame style.

According to some embodiments, the lens cavity size may conform to a same shape, ratio, and/or proportion of the front frame. The lens cavity size may have a smaller grooved interior channel, which may allow the lenses to snap fit into place. In an exemplary embodiment, the lens cavity may cover the ectocanthion 9/10 and the ectocanthus 11/12. The eye length 406 may indicate a minimal lens cavity size. In some embodiments, the lens cavity size may be defined within the stretchable parametric model by an adjustable parameter of the plurality of adjustable parameters.

According to some embodiments, the eyeglasses arm may be modeled by a wide blade shape with a scallop for an ear pinna. The arm length, in some embodiments, may be established using the ear top point UEBP 25/26, the ear back point IMP 27/28, and the ear back middle point PEBP 29/30. The arm breadth 508 may require a relative “snug” fit on the head width. A distance between the two arms may need to be less than the head breadth X to allow the arms to grip the head. A distance between the two ear top points UEBP 25/26 may be selected, and arm dimensions may be adjusted using a smaller negative dimensions. In an exemplary embodiment, the smaller negative dimensions may allow the arms to grip the top of the ear areas snugly to hold the custom eyewear frame in place. The “snug” fit may be determined based on the opinions of the user, or the user preference. A shape of the rear portion of the arm which may contact the back of the ear may affect the comfort. In an example embodiment, the stretchable parametric model may use a scalloped contour based at least in part on a curvature of a back ear contour. The back ear contour may be extracted from the UEBP 25/26, PEBP 29/30, and IMP 27/28. The UEBP 25/26, the PEBP 29/30, and the IMP 27/28 may be interpolated into a smooth curve. The interpolation, in an exemplary embodiment, may be completed in a parametric algorithm. The interpolation may define and construct the shape of the rear ear hang portion, and may ensure contact of the eyewear arms.

According to some embodiments, the nose bridge contour 410 can be designed to rest lightly on the sides of the nose. The nose bridge contour 410 may create a contact fit with the skin surface of the user. The nose bridge contour 410 may be used to design a morphologically accurate nose bridge shape. The nose bridge contour 410 may be accurately extracted by interpolating the nasal root points 3/4 and the sellion point 0. In effect, the nose bridge component on the custom eyewear frame can be designed to fit all morphologies around the nasal area. The stretchable parametric model, in some embodiments, may also include the plurality of adjustable parameters to fine-tune the nose bridge contour for improved fit.

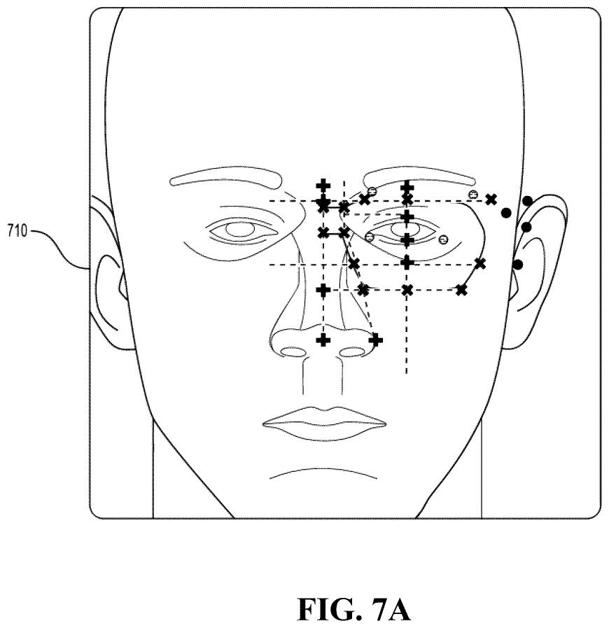

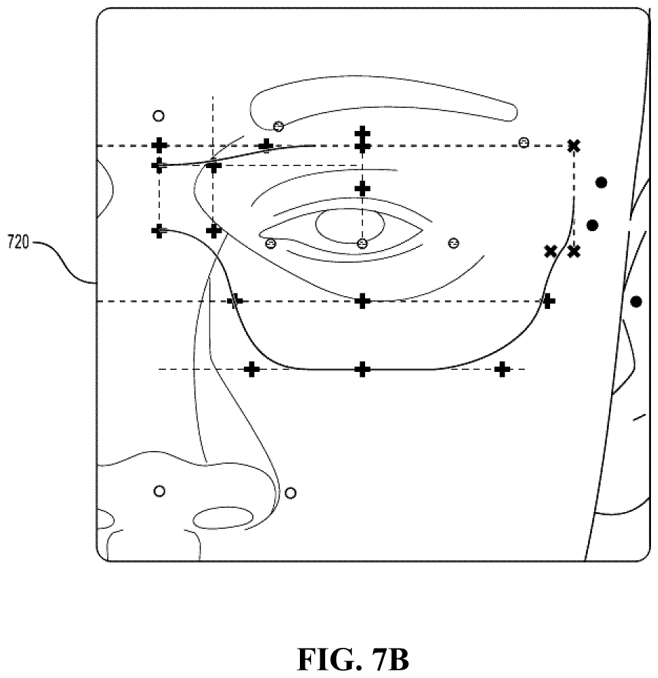

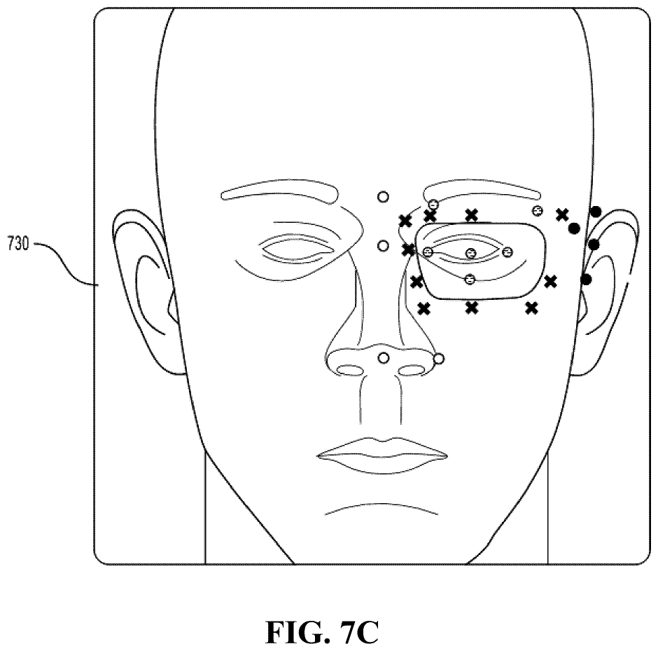

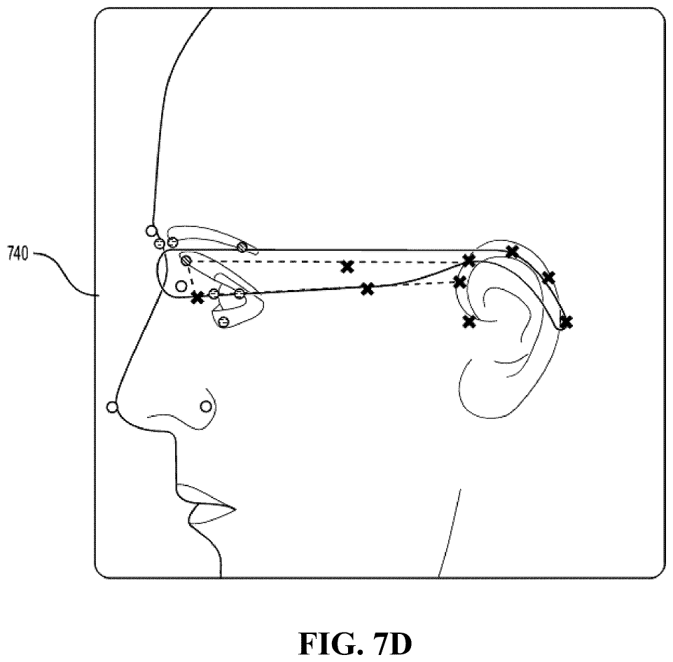

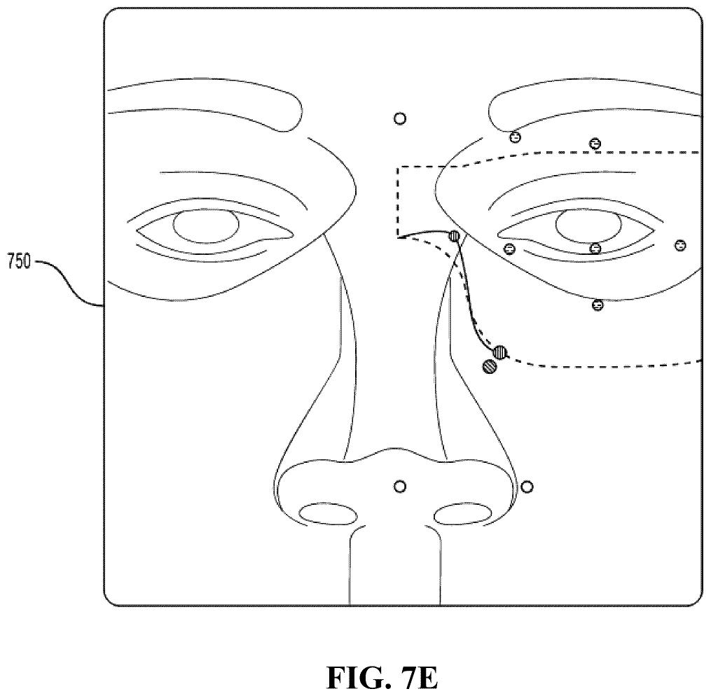

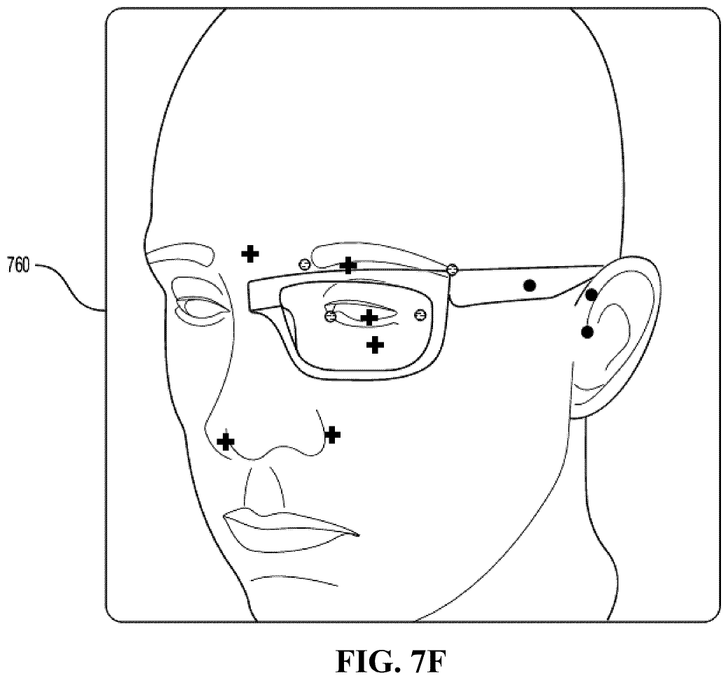

Referring to FIGS. 7A-7F, an exemplary embodiment of constructing the stretchable parametric model is illustrated. Constructing the stretchable parametric model can include a front frame contour step 710, a hinge step 720, a lens cavity contour step 730, an arm contour step 740, a nose pad contour step 750, a half frame step 760, or any combination thereof. In some embodiments, the front frame contour step 710 may include adjusting the front frame contour 710. For example, adjusting the front frame contour may be based at least in part on the plurality of landmarks, the plurality of facial dimensions, or any combination thereof. In some embodiments, the hinge step 720 may include adding the hinge 507. Adding the hinge 507, in an exemplary embodiment, may be based at least in part on the eyebrow lateral point 17, the temple point 31, or any combination thereof. In some embodiments, the lens cavity contour step 730 may include adjusting the lens cavity contour. Adjusting the lens cavity contour may be based at least in part on the frame contour. In some embodiments, the arm contour step 740 may include adjusting the arm contour. Adjusting the arm contour, in an exemplary embodiment, may be based at least in part on the hinge 507, ear landmarks, or any combination thereof. In some embodiments, the nose pad contour step 750 may include adjusting the nose pad contour. Adjusting the nose pad contour, in an exemplary embodiment, may be based at least in part on the sellion 0, the nasal root point 3, an adjustive point, or any combination thereof. In some embodiments, the half frame step 760 may include constructing a half frame. Constructing the half frame, in an exemplary embodiment, may include assembling the front frame contour, the hinge 507, the lens cavity contour, the arm contour, the nose pad contour, or any combination thereof. In an exemplary embodiment, generating the stretchable parametric model may be based at least in part on constructing the parametric model and positioning the parametric model.

According to some embodiments, generating the stretchable parametric model may further include selecting a generic eyewear frame design from a plurality of generic eyewear frame designs. The generic eyewear frame design, in some embodiments, can be selected by the user. In one embodiment, the generic eyewear frame design is selected based at least in part on one or more user preferences. In some embodiments, the generic eyewear frame design may constrain the set of body parameters. In some embodiments, the generic eyewear frame design may constrain the range of acceptable values for the set of adjustable parameters.

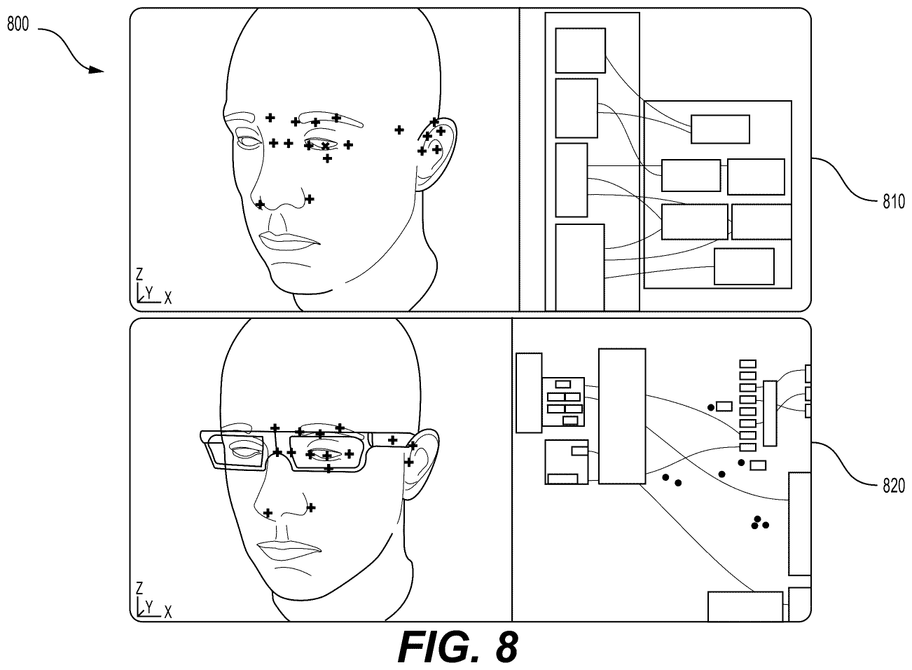

Referring to FIG. 8, an exemplary embodiment of an algorithm 800 for generating the stretchable parametric model is illustrated. The algorithm 800 may include at least step 810, step 820, or any combination thereof. Step 810, in some embodiments, may include inputting the plurality of landmarks into the algorithm 800. In an exemplary embodiment, the set of body parameters are automatically generated via the algorithm 800 based at least in part on the plurality of landmarks. In one embodiment, the plurality of facial dimensions can be extracted via the algorithm by using distance computation, or can be manually entered after being digitally measured. Step 820, in some embodiments, may include generating a default eyewear frame structure. In some embodiments, the default eyewear frame structure may be the stretchable parametric model. The default eyewear frame structure, in some embodiments, is based at least in part on the set of body parameters and the selected generic eyewear frame design.

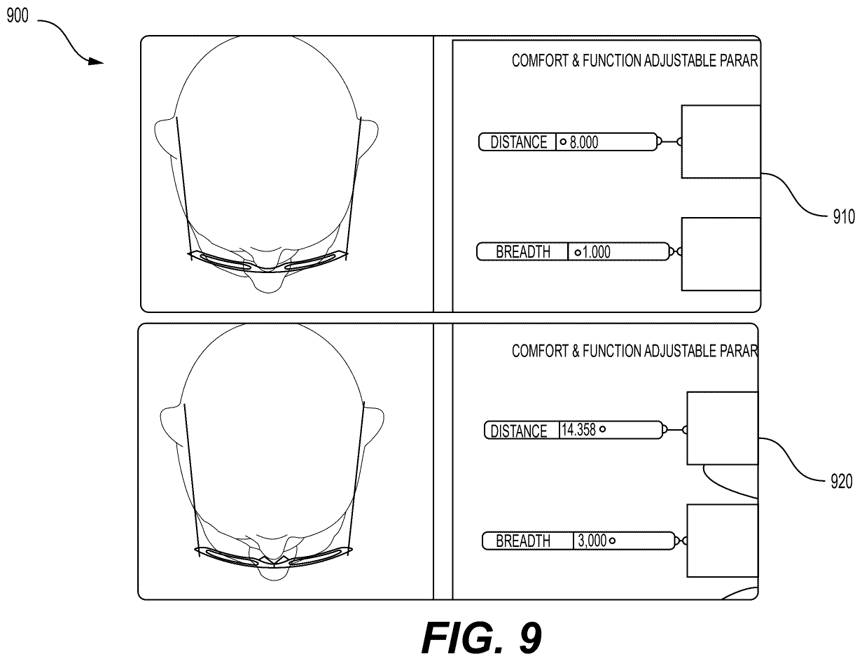

Referring to FIG. 9, an exemplary embodiment of an interface 900 for adjusting the values for the plurality of adjustable parameters is illustrated. In some embodiments, minimum and maximum values may be set for the plurality of adjustable parameters. For example, as shown in configuration 910 of FIG. 9, the vertex distance 503 and the arm breadth 508 are set at minimum values initially. This minimum may allow for the front frame to sit tightly on the face with a certain minimum distance from the pupil, as well as shrink the two arms inward slightly in order to properly sit from the scan. In another example embodiment, as shown in configuration 920 of FIG. 9, the vertex distance 503 and the arm breadth 508 may be set at moderate and maximum values. This setting may sit for the front frame to sit at a moderate distance, as well as shrink the two arms inward and grab the head more tightly.

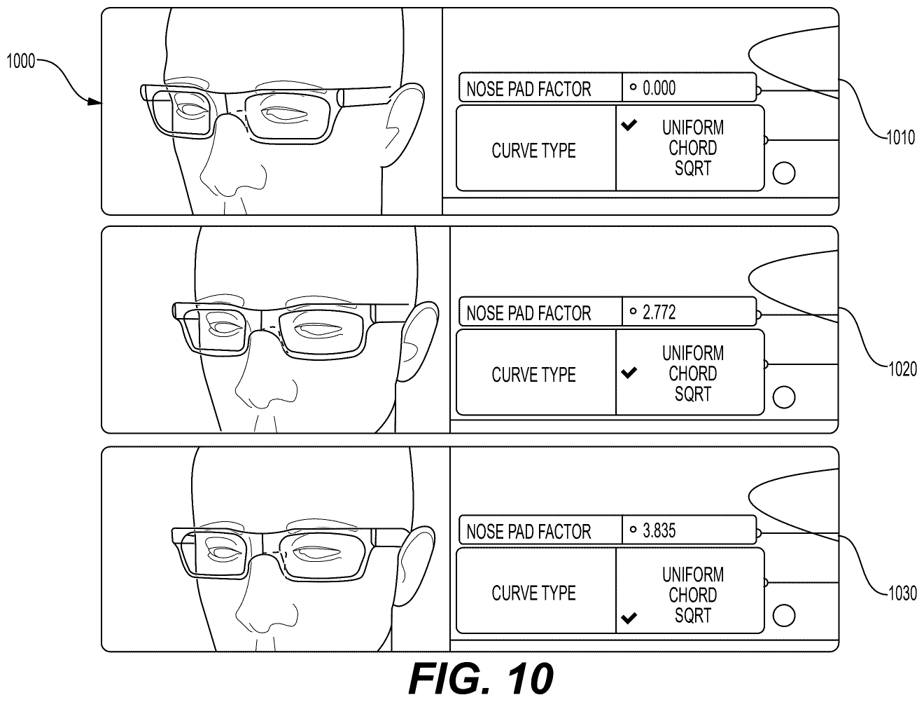

Referring to FIG. 10, an exemplary embodiment of an interface 1000 for adjusting the values for the plurality of adjustable parameters associated with the nose bridge 510 is illustrated. In some embodiments, the plurality of adjustable parameters associated with the nose bridge 510 may include a nose pad factor, a curve type, or any combination thereof. In one embodiment, a depth of the nose bridge with respect to the user's face is based at least in part on the nose pad factor. In some embodiments, a greater nose pad factor is associated with a tighter fit. The curve type, in some embodiments, may include a uniform curve type 1010, a chord curve type 1020, a SQRT curve type 1030, or any combination thereof. In some embodiments, the user preference may include the nose pad factor, the curve type, or any combination thereof. The curve type, in some embodiments, can define the shape of the nose pad contour.

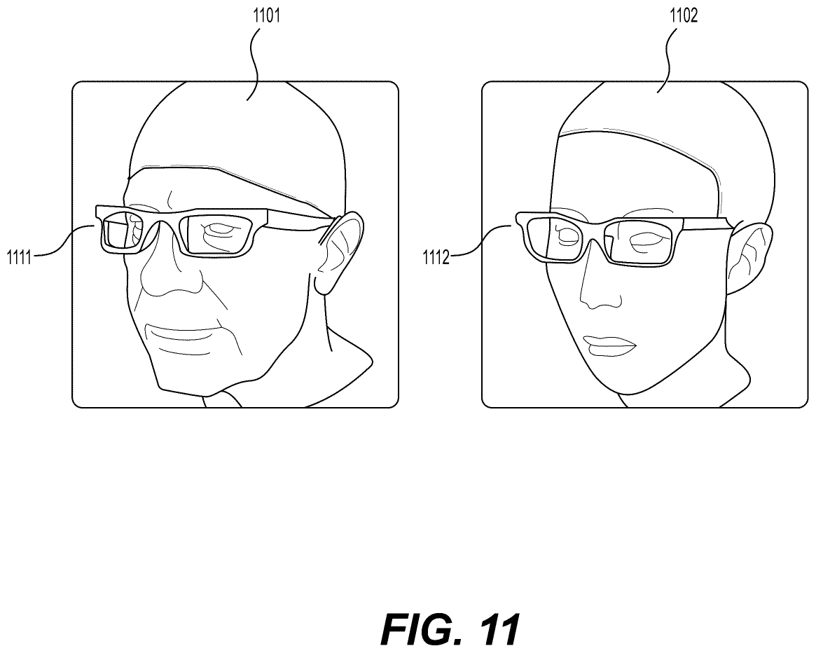

Referring to FIG. 11, an exemplary embodiment of a first user having a first model 1101 and a first custom eyewear frame 1111 and a second user having a second model 1102 and a second custom eyewear frame 1112 is illustrated. In some embodiments, the first model 1101 and the second model 1102 may include the plurality of landmarks. In one embodiment, the first model 1101 may include one or more landmarks of the plurality of landmarks that the second model 1102 may lack. In some embodiments, the first custom eyewear frame 1111 may be generated based at least in part on a first user preference. In some embodiments, the second custom eyewear frame 1112 may be generated based at least in part on a second user preference. In an exemplary embodiment, the first custom eyewear frame 1111 and the second custom eyewear frame 1112 are generated based at least in part on the algorithm 800.

The methods disclosed herein may be implemented using a 3D modeling software. In some embodiments, the 3D modeling software may be the Rhino 3D modeling software. The 3D modeling software, in some embodiments, may include a parametrizing plug-in. In an exemplary embodiment, the parametrizing plug-in may be the Grasshopper plug-in. The 3D modeling software, in some embodiments, can be used to manually select the plurality of landmarks. The 3D modeling software may receive a scan of at least a portion of a head of a user. The 3D modeling software may generate the set of body parameters based at least in part on the plurality of landmarks. The 3D modeling software, in an exemplary embodiment, may generate the stretchable parametric model. The 3D modeling software may generate the custom eyewear frame design data file based at least in part on the stretchable parametric model and the values for the set of adjustable parameters. The parametrizing plug-in, in an exemplary embodiment, may generate the set of body parameters via the algorithm 800. The 3D modeling software, in some embodiments may provide the interface 900, the interface 1000, or any combination thereof. The 3D modeling software, in exemplary embodiments, can provide an interface for inputting the one or more user preferences to alter the values for the set of adjustable parameters.

The methods disclosed herein can further comprise fabricating the custom eyewear frame. Fabricating the custom eyewear frame, in some embodiments, can be based at least in part on the custom eyewear frame design data file. In an exemplary embodiment, fabricating the custom eyewear frame can comprise: generating a CAD model of the custom frame based, at least in part, on the custom eyewear frame design data file; and manufacturing the CAD model via additive manufacturing. In some embodiments, at least a portion of the custom eyewear frame may be manufactured via traditional manufacturing methods. Traditional manufacturing methods may include CNC, molding, or any combination thereof. In one embodiment, the custom eyewear frame has a modular design. The modular design, in some embodiments, may comprise one or more parts manufactured via traditional manufacturing methods.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way.

What is claimed is:

1. A method for creating custom eyewear, comprising:
obtaining a model of at least a portion of a head of a user comprising a plurality of user features;
determining a set of body parameters based at least in part on the plurality of user features, wherein the set of body parameters comprises a plurality of landmarks;
determining values for a set of adjustable parameters; and
generating a custom eyewear frame design data file based at least in part on the set of body parameters and the set of adjustable parameters.

2. The method of claim 1, further comprising fabricating a custom eyewear frame based at least in part on the custom eyewear frame design data file.

3. The method of claim 1, further comprising selecting a generic eyewear frame design from a plurality of generic eyewear frame designs, wherein the set of adjustable parameters is associated with the generic eyewear frame design.

4. The method of claim 1, wherein the set of body parameters further comprises a plurality of facial dimensions based at least in part on the plurality of landmarks.

5. The method of claim 3, wherein the plurality of facial dimensions comprises forehead contour, nasial tilt, pupil position, eye orbit length, eye orbit height, eye length, hinge, head breadth, back of ear contour, nose bridge contour, or any combination thereof.

6. The method of claim 1, wherein the set of adjustable parameters comprises:
one or more of aesthetic parameters; and
one or more comfort factors,
wherein the values for the set of adjustable parameters are based at least in part on one or more user preferences.

7. The method of claim 4, wherein the one or more aesthetic parameters comprise frame style, lens size, arm style, arm length, frame width, or any combination thereof.

8. The method of claim 4, wherein the one or more comfort factors comprise a vertex distance, an arm breadth, a nose pad, a frame grip, or any combination thereof.

9. The method of claim 1, wherein generating the custom eyewear frame design data file comprises:
determining a set of fit factors;
generating a stretchable parametric model based at least in part on the set of body parameters and the set of fit factors; and
generating the custom eyewear frame design data file based at least in part on the stretchable parametric model and the values for the set of adjustable parameters.

10. The method of claim 8, wherein the set of fit factors comprises a quantitative fit factor, a contact fit factor, an interference fit factor, a ventilated fit factor, or any combination thereof.

11. The method of claim 8, wherein generating the custom eyewear frame design data file further comprises manually adjusting the values for the set of adjustable parameters to alter the stretchable parametric model.

12. The method of claim 2, wherein fabricating the custom eyewear frame comprises:
generating a CAD model of the custom eyewear frame based, at least in part, on the custom eyewear frame design data file; and
manufacturing the CAD model via additive manufacturing.

13. A method for creating custom eyewear, comprising:
receiving a scan of at least a portion of a head of a user;
identifying a plurality of landmarks based at least in part on the scan;
determining a set of body parameters based at least in part on the plurality of landmarks;
generating a stretchable parametric model based at least in part on the set of body parameters;
determining values for a set of adjustable parameters associated with the stretchable parametric model; and
generating a custom eyewear frame design data file based at least in part on the stretchable parametric model and the values for the set of adjustable parameters.

14. The method of claim 12, further comprising fabricating a custom eyewear frame based at least in part on the custom eyewear frame design data file.

15. The method of claim 12, wherein identifying the plurality of landmarks comprises:
inputting the scan into a landmark identification software; and
outputting, via the landmark identification software, a coordinate location of each of the plurality of landmarks.

16. The method of claim 12, wherein the stretchable parametric model is a wire-frame model.

17. The method of claim 12, wherein the stretchable parametric model is automatically generated based at least in part on the set of body parameters.

18. The method of claim 12, wherein the stretchable parametric model comprises one or more front frames, one or more lens cavities, one or more hinges, one or more arms, a nose bridge, or any combination thereof.

19. The method of claim 12, wherein the stretchable parametric model is based at least in part on body product relationship.

20. The method of claim 18, wherein the body product relationship is based at least in part on a front frame position, a face wrap, a pantoscopic tilt, a vertex distance, a front frame size, a hinge component, a lens cavity size, an eyeglasses arm, a nose bridge, or any combination thereof.
